(19) United States
(12) Patent Application Publication
(10) Pub. No.: US 2022/0021400 A1
(43) Pub. Date: Jan. 20, 2022

(54) ITERATIVE DECODER FOR DECODING A CODE COMPOSED OF AT LEAST TWO CONSTRAINT NODES

(71) Applicant: Université de Bretagne Sud, LORIENT (FR)

(72) Inventors: Emmanuel BOUTILLON, LORIENT (FR); Franklin Rafael COCHACHIN HENOSTROZA, LORIENT (FR)

(21) Appl. No.: 17/299,461

(22) PCT Filed: Dec. 3, 2019
(86) PCT No.: PCT/EP2019/083544

§ 371 Date: Jun. 3, 2021

(30) Foreign Application Priority Data
Dec. 3, 2018 (EP) 18306599.4

(51) Int. Cl. H03M 13/11; H03M 13/00; H03M 13/39

(52) U.S. Cl. CPC H03M 13/1117; H03M 13/1131; H03M 13/3927; H03M 13/6577; H03M 13/1128

(57) ABSTRACT

An iterative decoder, comprises:

N variable nodes (VNs) vₙ, n=1 . . . N, configured to receive a LLR Iₙ defined on a alphabet Aₗ of q_{ch} quantization bits, q_{ch}≥2;

M constraint nodes (CNs) cₘ, m=1 . . . M, 2≤M<N;

vₙ and cₘ exchanging messages along edges of a Tanner graph;

each vₙ sending messages mᵥ_{ₙ}_{→c}_{ₘ}, the set of connected constraint nodes being noted V₍ᵥₙ₎, and V_{(vn)\{cm}} being V₍ᵥₙ₎ except cₘ, and,

each cₘ sending messages m_{c}_{ₘ}_{→v}_{ₙ} to vₙ;

the LLR Iₙ and the messages mᵥ_{ₙ}_{→c}_{ₘ} and m_{c}_{ₘ}_{→v}_{ₙ} are coded; and

each variable node vₙ, for each iteration l, compute:

sign-preserving factors:

$$= ξ \times sign ( {I}_{n} ) + {\sum }_{c ∈ V ( {v}_{n} ) \backslash \{ {c}_{m} \}} sign ( )$$

where ξis a positive or a null integer;

$$= {I}_{n} + \frac{1}{2} \times + {\sum }_{c ∈ V ( {v}_{n} ) \backslash \{ {c}_{m} \}} ( )$$

and

[symbol]

=(sign( [symbol] ), [symbol] (floor(abs( [symbol] )))) where S is a function from the set of value that can take floor (abs( [symbol] )) to the set Aₛ.

### TECHNICAL FIELD

Various example embodiments relate to iterative decoding of a code composed of at least two constraint nodes, such as turbocodes or LDPC (Low Density Parity Check) codes.

### BACKGROUND

During the past two decades, Turbocodes and Low Density Parity Check (LDPC) codes have emerged as a crucial component of many communication standards. These codes can offer performance close to the Shannon limit for error rates above the decoder's error floor.

Particularly, LDPC codes are widely used in communications standards like DVB-S2, DVB-S2X, IEEE 802.3, etc. LDPC codes can be efficiently decoded by Message-Passing (MP) algorithms that use a Tanner graph representation of the LDPC codes. The Belief-Propagation (BP) decoder has excellent decoding performance in the waterfall region but at a cost of a high computational complexity. The Min-Sum (MS) and Offset Min-Sum (OMS) decoders are simplified version of the BP that are much less complex but at a cost of a slight decoding performance degradation in the waterfall region. Reducing the bit-size representation of message is a technique that further reduces the complexity of the decoder, again, at a cost of performance loss.

In the last fifteen years, the quantization problem has been extensively studied over the Binary-Input Additive White Gaussian Noise (BI-AWGN) channel. From these works, it can be concluded that 6 bits of quantization gives almost optimal performance. It can also be observed that all paper on finite precision use the “no-decision value”, i.e., a Log-Likelihood Ratio (LLR) equal to 0 (without defined sign, thus) in their messages representation. This is also true for the recent work on Non-surjective Finite Alphabet Iterative Decoders (NS-FAIDs) which provides a unified framework for several MS-based decoders like Normalized MS (NMS), OMS, Partially OMS.

In “Improved low-complexity low-density parity-check decoding”, Cuiz et al., a weighted bit-flipping (WBF) algorithm is proposed called improved modified WBF (IMWBF). The IMWBF uses the bit of sign plus an extra bit to give a weight to the message, thus, exchange messages are on two bits. However, like all Bit Flipping algorithm, the same message it broadcasted by a given variable node to its associated check nodes.

In “Non-surjective finite alphabet iterative decoders”, Nguyen-Ly Thien Truong et al.

and “Finite alphabet Iterative Decoders-Part I: Decoding Beyond Belief Propagation on the Binary Symmetric Channel”, Shiva Kumar Planjery et al., the authors propose an algorithm named Non-Surjective Finite Alphabet Iterative Decoder (NS-FAID). A characteristic of this algorithm is that the 0 value is encoded in all the messages it exchanges.

### SUMMARY

However, from all these work, it appears there is still a need for a decoder having good performance with a relative low complexity, i.e. a decoder which works well with few quantization bits.

In a first example embodiment, an iterative decoder is configured for decoding a code composed of at least two constraint nodes and having a codeword length N, said decoder comprising:
N variable nodes (VNs) vₙ, n=1 . . . N, each variable node vₙ being configured to receive a log-likelihood ratio LLR Iₙ of the channel decoded bit n of the codeword to be decoded, said LLR Iₙ being defined on a alphabet Aₛ of q quantization bits, q being an integer equal or greater than 2;
M constraint nodes (CNs) cₘ, m=1 . . . M, 2≤M<N;
the variable nodes and the constraint nodes being the nodes of a Tanner graph; variable nodes and constraint nodes being configured to exchange messages along edges of the Tanner graph;
each variable node vₙ being configured for estimating the value yₙ of the n^{th} bit of the codeword to be decoded and for sending messages mᵥ_{ₙ}_{→c}_{ₘ}, messages belonging to Aₛ, to the connected constraint nodes cₘ, the set of connected constraint nodes being noted V₍ᵥₙ₎, defining the degree dᵥ of the variable node vₙ as the size of the set V₍ᵥₙ₎, and V_{(vn)\{cm}} being the set V₍ᵥₙ₎ except the constraint node cₘ, and then,
each constraint nodes cₘ being configured for testing the received message contents with predetermined constraints and sending messages m_{c}_{ₘ}_{→v}_{ₙ}, messages belonging to an alphabet A_{c}, to the connected variable nodes vₙ;
the message emissions being repeated until the decoding of the codeword is achieved successfully or a predetermined number of iteration is reached; and
the LLR Iₙ and the messages mᵥ_{ₙ}_{→c}_{ₘ} and m_{c}_{ₘ}_{→v}_{ₙ} are coded according to a sign-and-magnitude code in the alphabets Aₛ and A_{c} symmetric around zero, Aₛ={−N_{q}, . . . , −1, −0, +0, +1, . . . ,+N_{q}}, A_{c}={−N_{q′}, . . . , −1, −0, +0, +1, . . . ,+N_{q′}} in which the sign indicates the estimated bit value and the magnitude represents its reliability; and
each variable node vₙ, for each iteration l, is configured to compute:
sign-preserving factors, sum of the ponderated sign of LLR Iₙ and the sum of the signs of all messages, except for the message coming from cₘ, received from the connected constraint nodes at iteration /:
   [symbol] =ξ×sign (Iₙ)+Σ_{c∈V(v}_{ₙ}_{)\{c}_{ₘ}_{}} sign ( [symbol] ) where ξis a positive or a null integer;
messages to connected constraint nodes cₘ for iteration l+1 computed in two steps
   [symbol] =lₙ+½× [symbol] +Σ_{c∈V(v}_{ₙ}_{)\{c}_{ₘ}_{}} ( [symbol] ) and
   [symbol] =(sign( [symbol] ), [symbol] (floor(abs( [symbol] )))) where S is a function from the set of value that can take floor (abs( [symbol] )) to the set Aₛ.

Advantageously, the decoder uses an implementation that always preserve the sign of the messages. Consequently, it can achieve the same convergence threshold as a classical decoder using a representation with more bits.

This embodiment may comprises other features, alone or in combination, such as:
ξ equal to 0 if dᵥ=2, equal to 1 if dᵥ>2 and dᵥ is odd, and equal to 2 if dᵥ>2 and dᵥ is even;
the constraints applied by the constraint nodes are parity check, convolution code or any block code;
the codeword is coded by LDPC and the constraint nodes are check nodes;
the function S is defined as S(x)=min(max(x−λ(x), 0),+Nq), where λ(x) is an integer offset value depending on the value of x;
λ(x) is a random variable that can take it value in a predefined set of values according to a predefined law;
alphabets Aₛ and A_{c} are identical; and/or
the means comprises
at least one processor; and
at least one memory including computer program code, the at least one memory and computer program code configured to, with the at least one processor, cause the performance of the decoder.

In a second example embodiment, an iterative decoding method for decoding a code composed of at least two constraint nodes and having a codeword length N, by an iterative decoder as disclosed here above, comprises:
reception and storage of the LLR Iₙ by the variable node vn, n=1 . . . N;
emission of messages mᵥ_{ₙ}_{→c}_{ₘ};
verification of the constraints by the constraint nodes cₘ;
emission of messages m_{c}_{ₘ}_{→v}_{ₙ} containing a possible candidate value for the variable n solving the constraints;
computation by the variable nodes of [symbol] =ξ×sign (Iₙ)+Σ_{c∈V(v}_{ₙ}_{)\{c}_{ₘ}_{}} sign( [symbol] ) where ξ is a positive or a null integer, and of messages to connected constraint nodes cₘ for iteration l+1 computed in two steps
[symbol] =Iₙ+½× [symbol] +Σ_{c∈V(v}_{ₙ}_{)\{c}_{ₘ}_{}} ( [symbol] ) and
[symbol] =(sign( [symbol] ), [symbol] (floor(abs( [symbol] )))) where S is a function from the set of value that can take floor (abs( [symbol] )) to the set Aₛ; and.
iteration from emission of messages mᵥ_{ₙ}_{→c}_{ₘ} to their computation for the next iteration until the codeword is decoded or the number of iteration reaches a predetermined count.

In a third example embodiment, a digital data storage medium is encoding a machine-executable program of instructions to perform the method disclosed here above.

### BRIEF DESCRIPTION OF THE FIGURES

Some embodiments are now described, by way of example only, and with reference to the accompagnying drawings, in which:

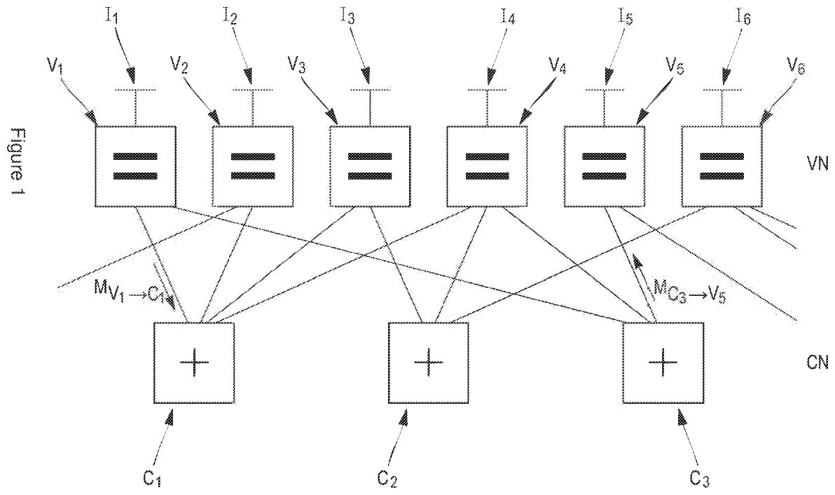

The FIG. 1 schematically illustrates an iterative decoder;

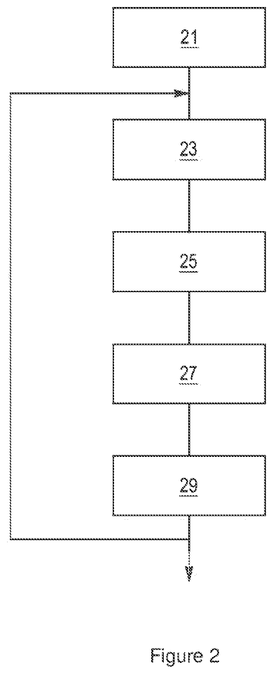

The FIG. 2 illustrates a flow chart of an iterative decoding method;

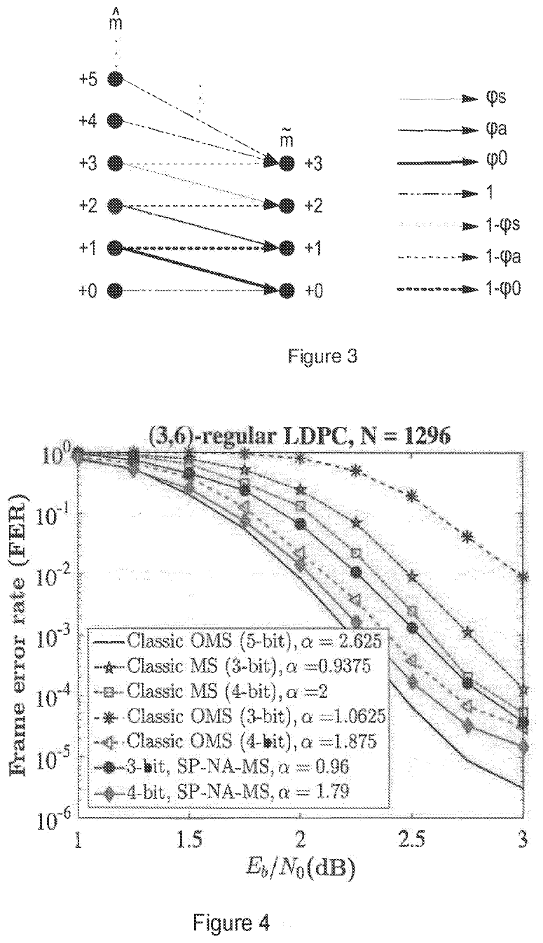

The FIG. 3 schematically illustrate a mapping used for the noise model γ;

The FIG. 4 illustrates the FER performance of MS and SP-MS decoders for (3, 6)-regular LDPC code;

The FIG. 5 illustrates the FER performance of MS and SP-MS decoders for (4, 8)-regular LDPC code;

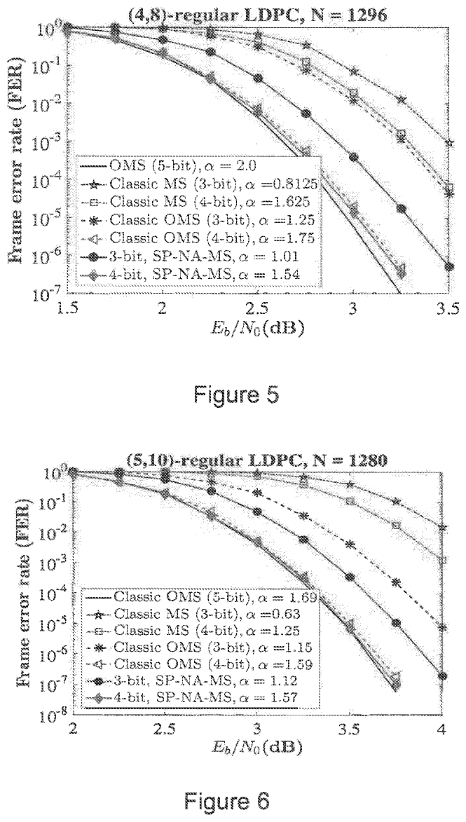

The FIG. 6 illustrates the FER performance of MS and SP-MS decoders for (5, 10)-regular LDPC code;

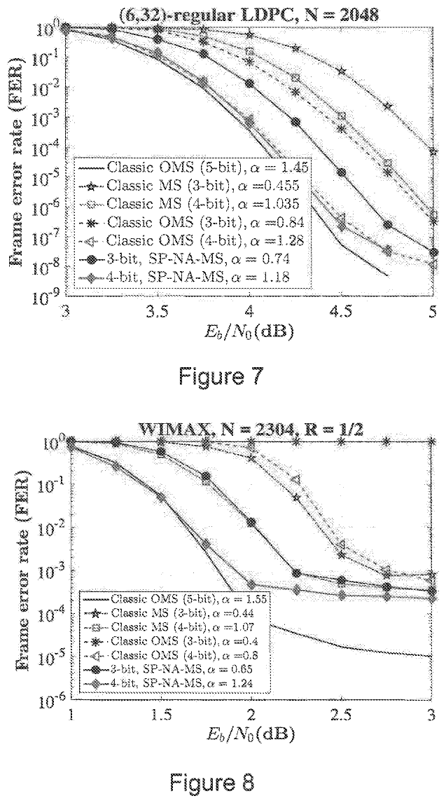

The FIG. 7 illustrates the FER performance of MS and SP-MS decoders for the IEEE 802.3 ETHERNET code;

The FIG. 8 illustrates the FER performance of MS and SP-MS decoders for the WIMAX rate 1/2 LDPC code;

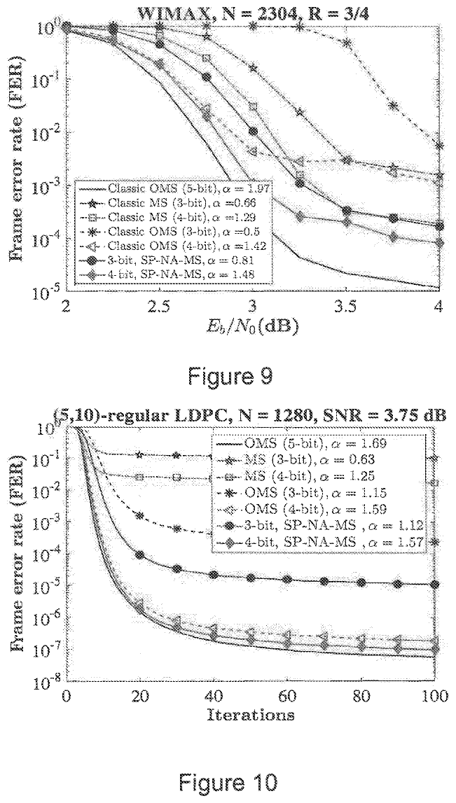

The FIG. 9 illustrates the FER performance of MS and SP-MS decoders for the WIMAX rate 3/4 B LDPC code;

The FIG. 10 illustrates the FER convergence comparison on (5, 10)-regular LDPC code at E_{b}/N₀=3.75 dB;

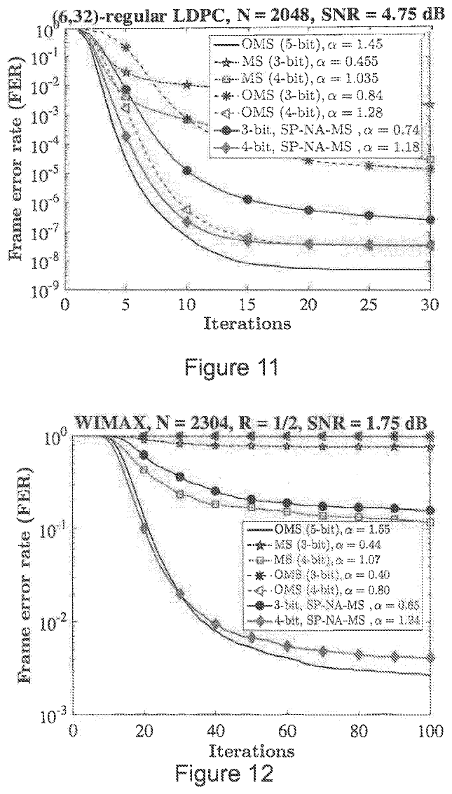

The FIG. 11 illustrates the FER convergence comparison on the IEEE 802.3 ETHERNET code at E_{b}/N₀=4.75 dB;

The FIG. 12 illustrates the FER convergence comparison on the WIMAX rate 1/2 LDPC code at E_{b}/N₀=1.75 dB; and

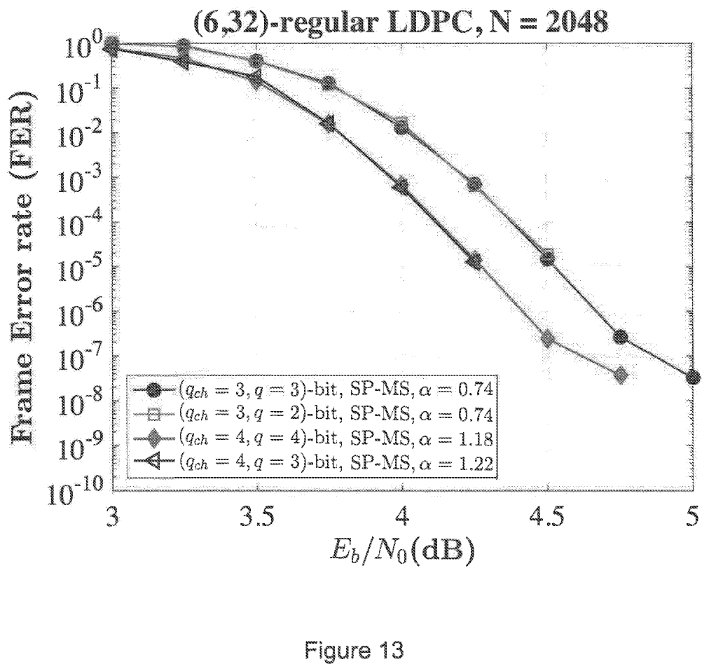

The FIG. 13 illustrates the FER performance of MS and SP-MS decoders for the IEEE 802.3 ETHERNET code with various alphabet lengths.

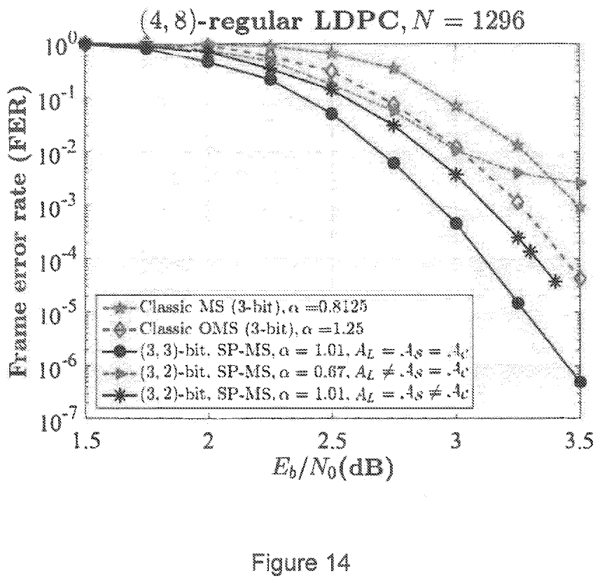

The FIG. 14 illustrates the performances of the SP-MS decoder in comparison with other decoders.

### DESCRIPTION OF EMBODIMENTS

As a preliminary remark, the following described embodiments are focused on LDPC codes. However, the man skilled in the art may transpose without particular difficulties, the teaching to a code having at least two constraint nodes, particularly turbocodes. In the latter case, the constraint nodes use convolution as predetermined rule.

In reference to FIG. 1, an iterative decoder 1 is configured for decoding LDPC codes having a codeword length N. It means that the message was coded on N bits.

In the illustrated example, N=6. However, in practice, the codeword length N is much larger and can be typically around 64 000.

The decoder 1 comprises N variable nodes (VNs) vₙ, n=1 . . . N. It means that the variable node vₙ receives the result Iₙ of the signal quantization for the bit n of the received message. The signal quantization will not be described further as it is a step well known from the man skilled in the art.

The result Iₙ is a combination of the estimated value, either 0 or 1, and a likelihood that this estimated value is the correct one expressed as a log-likelihood ratio LLR. Iₙ is defined on a alphabet A_{L} of q_{ch} quantization bits, q_{ch} being an integer equal or greater than 3.

Iₙ is coded on a particular alphabet A_{L}, or representation, called Sign-Magnitude. The alphabet is symmetric around zero. A_{L}={−N_{qch}, . . . , −1, −0, +0, +1, . . . , +N_{qch}} in which the sign indicates the estimated bit value and the magnitude represents its likelihood.

The following table gives the represention on 3 bits for a classical decoder using a 2-Complement representation and for the described decoder 1 using a Sign-Magnitude representation

| Estimated | | | Sign- |
|---|---|---|---|
| value | Likelihood | 2-Complement | Magnitude |
| 1 | 3 | 101 | 111 |
| 1 | 2 | 110 | 110 |
| 1 | 1 | 111 | 101 |
| 1 | 0 | 000 | 100 |
| 0 | 0 | | 000 |
| 0 | 1 | 001 | 001 |
| 0 | 2 | 010 | 010 |
| 0 | 3 | 011 | 011 |

The variable nodes VNs use for all their computation an alphabet Aₛ constructed similarly than the alphabet A_{L} but with q quantization bits, q≤q_{ch}.

The decoder 1 comprises also M constraint nodes CNs cₘ, m=1 . . . M, 2≤M<N.

The variable nodes VNs and the constraint nodes CNs are the nodes of a Tanner graph. The edges of the Tanner graph defines the relationship between variable nodes and constraint nodes along which they exchange messages.

The message sends by variable node vₙ to constraint node cₘ at iteration [symbol] is named [symbol] and the message sends by constraint node cₘ to variable node vₙ at iteration [symbol] is named

[symbol]

The set of constraint nodes connected in the Tanner graph to the variable node vₙ is named V(vₙ). The degree dᵥ of the variable node vₙ is defined as the size of the set V₍ᵥₙ₎, i.e. the number of constraint nodes connected to the variable node. And V_{(vn)\{cm}} is defined as the set V₍ᵥₙ₎ except the constraint node cₘ.

Each variable node vₙ estimates the value yₙ of the nth bit of the codeword to be decoded and send messages [symbol] ,messages belonging to Aₛ, to the connected constraint nodes cₘ.

At the first iteration, each variable node vₙ sends to its connected constraint nodes the value Iₙ.

At each iteration [symbol] , [symbol] >1, each variable node vₙ computes sign-preserving factors [symbol] which are the sum of the ponderated sign of LLR Iₙ and the sum of the signs of all messages, except for the message coming from cₘ, received from the connected constraint nodes. [symbol] =ξ×sign (Iₙ)+Σ_{c∈V(v}_{ₙ}_{)\{c}_{ₘ}_{}} sign ( [symbol] ) (1) where ξ is a positive or a null integer.

ξ is equal to 0 if dᵥ=2, equal to 1 if dᵥ>2 and dᵥ is odd, and equal to 2 if dᵥ>2 and dᵥ is even.

Then the variable node vₙ compute the messages to send to the constraint nodes cₘ for iteration [symbol] +1 in two steps. [symbol] =Iₙ+½× [symbol] +Σ_{c∈V(v}_{ₙ}_{)\{c}_{ₘ}_{}(} [symbol] _{) (}2) and [symbol] =(sign( [symbol] ), [symbol] (floor(abs( [symbol] )))) (3) where S is a function from the set of value that can take floor (abs( [symbol] )) to the set Aₛ.

Each constraint node cₘ tests the received message contents with predetermined constraints. The constraints may be parity check, convolution code or any block code. Typically for LDPC code, the constraint is parity check and the constraint nodes are thus named check nodes.

After analyzing the constraints, each constraint nodes cₘ sends messages [symbol] to the connected variable nodes vₙ.

The messages [symbol] belongs to an alphabet A_{c}. Alphabet A_{c} uses also a Sign-Magnitude representation but with a set of value similar or different than Aₛ. The alphabet Aₛ and A_{c} are thus symmetric around zero as A_{L}.

Alphabet Ac may use a Sign-Magnitude representation with a set of value similar or different than As in terms or cardinality, i.e. Ac could be equal to {−3,−2,−1,−0,+0,+1,+2,+3} while As can be equal to {−1,−0,+0,+1} for example. By “similar”, one should understand equal or approximatively equal.

In a particular embodiment, the function S may be defined as S(x)=min(max(x−λ(x), 0),+Nq), where λ(x) is an integer offset value depending on the value of x. More particularly, λ(x) is a random variable that can take its value in a predefined set of values according to a predefined law. A careful choice of the offset value will allow a smooth convergence of the iterative process by decreasing the impact of high likelihood during propagation.

The message emissions are repeated until the decoding of the codeword is achieved successfully or a predetermined number of iteration is reached.

Consequently, the method for decoding is the following, FIG. 2:
Reception and storage of the LLR Iₙ by the variable node vₙ, n=1 . . . N, step 21;
Emission of messages [symbol] step 23;
Verification of the constraints by the constraint nodes cₘ, step 25;
Emission of messages m_{c}_{ₘ}_{→v}_{ₙ}⁽¹⁾ containing a possible candidate value for the variable n solving the constraints, step 27;
Computation by the variable nodes of equations (1), (2) and (3), step 29;
Iteration of steps 23 to 29 until the codeword is decoded or the number of iteration reaches a predetermined count.

In the following sections, a comparison of classical quantized decoders with the disclosed decoder, which will be called Sign-Preserving Min-Sum (SP-MS) decoder, will be exposed as well as some theorical analysis and modelisation showing the improvements of the disclosed decoder. Finally, some experimental results will be disclosed.

### Basic Notions of Classical Quantized Decoders and LDPC Codes

An LDPC code is a linear block code defined by a sparse parity-check matrix H=[hₘₙ] of M rows by N columns, with M<N. The usual graphical representation of an LDPC code is made by a Tanner graph which is a bipartite graph G composed of two types of nodes, the variable nodes (VNs) vₙ, n=1 . . . N and the check nodes (CNs) cₘ, m=1 . . . M. A VN in the Tanner graph corresponds to a column of H and a CN corresponds to a row of H, with an edge connecting CN cₘ to VN vₙ exists if and only if hₘₙ≠0.

Let us assume that v is any VN and c is any CN. Let us also denote V(v) the set of neighbors of a VN v, and denote V(c) the set of neighbors of a CN c. The degree of a node is the number of its neighbors in G. A code is said to have a regular column-weight dᵥ=|V(v)| if all VNs v have the same degree dᵥ. Similarly, if all CNs c have the same degree d_{c}=|V(c)|, a code is said to have a regular row-weight d_{c}. In case of irregular LDPC codes, the nodes can have different connexion degrees, defining an irregularity distribution, which is usually characterized by the two polynomials λ(x)=Σᵢ₌₂^{d}^{_{v,max}} λᵢxⁱ⁻¹, and ρ(x)=Σⱼ₌₂^{d}^{_{c,max}} ρⱼx^{j-1}. The parameters λᵢ (respectively ρⱼ) indicate the fraction of edges connected to degree i VNs (respectively degree j CNs). For regular codes, the polynomials reduce to monomials, λ(x)=x^{d}⁻¹ and ρ(x)=x^{d}^{_{c}}⁻¹.

Let x=(x₁, . . . ,x_{N})∈{0,1}^{N} denote a codeword which satisfies Hx^{T}=0. In the following examples, x is mapped by the Binary Phase-Shift Keying (BPSK) modulation and transmitted over the BI-AWGN channel with noise variance σ². The channel output y=(y₁, . . . , y_{N}) is modeled by yₙ=(1−2xₙ)+zₙ for n=1, . . . , N, where zₙ is a sequence of independent and identically distributed (i.i.d.) Gaussian random variables with zero mean and variance σ². The decoder produces the vector \hat{x}=(\hat{x}₁, . . . ,\hat{x}_{N})∈{0,1}^{N} which is an estimation of x. To check if \hat{x} is a valid codeword, we verify that the syndrome vector is all-zero, i.e. H\hat{x}^{T}=0.

For classical quantized decoders the finite message alphabet [symbol] _{c} is defined as [symbol] _{c}={−N_{q}, . . . , −1,0,+1, . . . ,+N_{q}} and consists of Nₛ=2N_{q}+1 states, with N_{q}=2^{(q-1)}−1 where q is the number of quantization bits. Let us denote A_{L} the decoder input alphabet, and denote [symbol] ∈ [symbol] the iteration number. Let us also denote [symbol] ∈ [symbol] _{c} the message sent from VN v to CN c in the [symbol] ^{th} iteration, and denote [symbol] ∈ [symbol] _{c} the message sent from CN c to VN v in the [symbol] ^{th} iteration.

The LLR that can be computed at the channel output is equal to:

$$LLR ( {y}_{n} ) = log ( \frac{Pr ( {y}_{n} \vert {x}_{n} = 0 )}{Pr ( {y}_{n} \vert {x}_{n} = 1 )} ) = \frac{2 {y}_{n}}{{σ}^{2}} . \qquad ( 11 )$$

We assume that [symbol] _{c}=A_{L}, hence, LLR(yₙ) has to be quantized and saturated. For classical decoders, let us denote the quantizer by [symbol] : [symbol] →A_{L}, defined as

[symbol]

(a)= [symbol] (└α×a+0.5┘, N_{q}), (12)

where └ ┘depicts the floor function and [symbol] (b, N_{q}) is the saturation function clipping the value of b in the interval [−N_{q}, N_{q}], i.e. [symbol] (b, N_{q})=min (max (b, N_{q}),+N_{q}). The parameter α is called channel gain factor and is used to enlarge or decrease the standard deviation of quantized values at the decoder input. The value of α can be seen as an extra degree of freedom in the quantized decoder definition that can be analyzed and optimized for quantized decoders on the BI-AWGN channel. Note that if α is too large most of quantized values will be saturated to N_{q}. With those notations, we define the quantized version of the intrinsic LLR that initialize the classical decoder by the vector I=(I₁, . . . ,I_{N})∈ [symbol] _{C}^{N}, with

Iₙ= [symbol] (LLR(yₙ)) ∀n=1, . . . ,N. (13)

A MP decoder exchanges messages between VNs and CNs along edges using a Tanner graph. During each iteration, the VN update (VNU) and CN update (CNU) compute outgoing messages from all incoming messages.

Let us briefly recall the VNU and CNU equations for the Min-Sum based decoders, before introducing the Sign-Preserving Min-Sum (SP-MS) decoders. For this purpose, we define the discrete update functions for quantized Min-Sum based decoders. Let Ψᵥ:A_{L}× [symbol] _{c}^{(d}^{ᵥ}⁻¹⁾→ [symbol] _{c}, denote the discrete function used for the update at a VN v of degree dᵥ. Let Ψ_{c}: [symbol] _{c}^{(d}^{_{c}}⁻¹⁾→ [symbol] _{c}, denote the discrete function used for the update at a CN c of degree d_{c}.

Thus the update rule at a CNU is given by

$$= {Ψ}_{c} ( {\{ \}}_{v ∈ V ( {c}_{m} ) \backslash \{ {v}_{n} \}} ) = ( {\prod }_{v ∈ V ( {c}_{m} ) \backslash \{ {v}_{n} \}} sign ( ) ) . \qquad ( 14 )$$

And the update rule at a VNU is expressed as

[symbol]

=Ψᵥ(Iₙ, { [symbol] }_{c∈V(v}_{ₙ}_{)\{c}_{ₘ}_{}})=Λ( [symbol] ), (15)

where the function Λ(.) and the unsaturated v-to-c message [symbol] are defined by

Λ(a)=sign (a)× [symbol] (max(|a|−λᵥ, 0),N_{q}).

[symbol]

=Iₙ+∈_{c∈V(v}_{ₙ}_{)\{c}_{ₘ}_{}}

[symbol]

The alphabet of [symbol] , denoted [symbol] _{U}, is defined as [symbol] _{U}={−N_{q}×dᵥ, . . . ,−1,0,+1, . . . ,+N_{q}×dᵥ}. We define the classical OMS decoder with offset value λᵥ∈{+1, . . . ,+(N_{q}−2)}, where the special case of λᵥ=0 corresponds to the classical MS decoder. It must be noted that the discrete functions Ψᵥ and Ψ_{c} satisfy the symmetry conditions. Now, let us further [symbol] =( [symbol] , . . . , [symbol] ) denote the a posteriori probability (APP) in the [symbol] ^{th} iteration. Let us also denote [symbol] ₐₚₚ the alphabet of APPs with [symbol] ₐₚₚ={−N_{q}×(dᵥ+1), . . . ,−1,0,+1, . . . ,+N_{q}×(dᵥ+1)}. The APP [symbol] ∈ [symbol] ₐₚₚ is associated to a VN vₙ, n=1,2, . . . ,N. The APP update at a VN vₙ of classical MS-based decoders is given by

[symbol]

=Ψᵥ(Iₙ{ [symbol] }_{c∈V(v}_{ₙ}₎)=Iₙ+Σ_{c∈V(v}_{ₙ}₎ [symbol] (16)

From the APP, \hat{x}ₙ can be computed as \hat{x}ₙ=(1−sign ( [symbol] ))/2 if [symbol] ≠0, otherwise, \hat{x}ₙ=0 if Iₙ>0 and \hat{x}ₙ=1 if Iₙ≤0, for n=1, . . . ,N.

We must take into account that at the initialization of MP decoders, variable-to-check messages [symbol] are initialized by Iₙ at [symbol] =0, i.e. mᵥ_{ₙ}_{␣c}_{ₘ}⁽⁰⁾=Iₙ where vₙ ∈V(cₘ).

### Sign-Preserving Min-Sum (SP-MS) Decoders

In the classical MS-based decoders, the value of the v-to-c message can be zero, see (5). In that case, the erased message, i.e. [symbol] =0, does not carry any information and does not participate in the convergence of the decoder. In this paper, we propose a new type of decoder, with a modified VNU using a sign preserving factor, which never propagates erased messages.

### Quantization Used for SP-MS Decoders

Using the sign-and-magnitude representation one can obtain a message alphabet which is symmetric around zero and which is composed of Nₛ=2^{q} states. Hence the message alphabet for SP-MS decoders denoted by [symbol] ₛ is defined as [symbol] ₛ={−N_{q}, . . . ,−1,−0,+0,+1, . . . ,+N_{q}}. The sign of a message m ∈ [symbol] ₛ indicates the estimated bit value associated with the VN to or from which m is being passed while the magnitude |m| of m represents its reliability. In this paper, it is assumed that [symbol] _{L}=Aₛ. An example of the binary representation of [symbol] _{c} and [symbol] ₛ for q=3 is shown in Table 1, one can see that −0 is represented by 100₂, +0 is represented by 000₂, etc.

TABLE 1
Binary representation of the quantized values.

| | |
|---|---|
| Classical Decoder | Sign Preserving Decoder |

| m ϵ A_{C} | q = 3 bits | m ϵ A_{S} | q = 3 bits | (sign (m), \|m\|) |
|---|---|---|---|---|
| −3 | 101 | −3 | 111 | (−1, 3) |
| −2 | 110 | −2 | 110 | (−1, 2) |
| −1 | 111 | −1 | 101 | (−1, 1) |
| — | 100 | −0 | 100 | (−1, 0) |
| 0 | 000 | +0 | 000 | (+1, 0) |
| +1 | 001 | +1 | 001 | (+1, 1) |
| +2 | 010 | +2 | 010 | (+1, 2) |
| +3 | 011 | +3 | 011 | (+1, 3) |

The quantization process defined in (12) is replaced by

[symbol]

*(a)=(sign(a), [symbol] (┌a×|a|┐−1,N_{q})), (17)

where ┌ ┐ depicts the ceiling function. The quantized LLR is thus defined as Iₙ= [symbol] *(LLR(yₙ))∈ [symbol] ₛ for n=1, . . . ,N. Let us define the update rules for Sign-Preserving decoders.

### Sign-Preserving Min-Sum Decoders

One can note from (14) that the CNU by construction determines the sign of each outgoing message, thus the CNU generates outgoing messages that always belong to [symbol] ₛ, therefore, the CNU remains identical. In the case of the VNU, (15) should be modified to ensure that the outgoing message will always belong to [symbol] ₛ. To preserve always the sign of the messages, let us denote by [symbol] the sign-preserving factor of the message [symbol] , defined as

[symbol]

=ξ×sign(Iₙ)+Σ_{c∈V(v}_{ₙ}_{)\{c}_{ₘ}_{}}sign( [symbol] ), (18)

where the values of ξ depends on the value of the column-weight dᵥ of a VN vₙ, thus we have

$$ξ = \{ \begin{matrix}0 , & if & {d}_{v} = 2 , \\ 1 , & if & {d}_{v} > 2 and ( {d}_{v} mod 2 ) = 1 , \\ 2 , & if & {d}_{v} > 2 and ( {d}_{v} mod 2 ) = 0.\end{matrix} \qquad ( 19 )$$

Note that the other values of ξ give worse decoding performance.

From (18), one can note that, by construction, [symbol] is the sum of dᵥ (resp. dᵥ+1) values in {−1, +1} if dᵥ is odd (resp. if dᵥ is even and greater than 2), and [symbol] ∈{−1, +1} for the special case of dᵥ =2. Thus, [symbol] is always an odd number.

The update rule of the Sign-Preserving Offset Min-Sum (SP-OMS) VNU is changed from (5) to

[symbol]

=Ψᵥ(Iₙ,{ [symbol] }_{c∈V(v}_{ₙ}_{)\{c}_{ₘ}_{}})=(sign( [symbol] ), [symbol] (max(| [symbol] |−λᵥ, 0),N_{q})) (20)

where [symbol] is the unsaturated v-to-c message of Sign-Preserving decoders, given by

$$= {Λ}^{*} ( \frac{2}{} + {I}_{n} + {\sum }_{c ∈ V ( {v}_{n} ) \backslash \{ {c}_{m} \}} ) ,$$

the function Λ*(.) is defined by Λ*(a)=(sign(a),└|a|┘). Note that Λ*(.) is applied on a non-null value since by construction, the fractional part of ( [symbol] )/2 is 0.5.

We define a Sign-Preserving Min-Sum (SP-MS) decoder by setting λᵥ=0. For Sign-Preserving decoders, we have [symbol] _{U}={−N_{q}×dᵥ−└dᵥ/2┘), . . . , −1,−0,+0,+1, . . . , +N_{q}×dᵥ+└dᵥ/2┘}.

The APP update at a VN vₙ of Sign-Preserving decoders is given by

[symbol]

=Ψᵥ(Iₙ,{ [symbol] }_{c∈V(v}_{ₙ}₎)=Iₙ+½×ξ×sign(Iₙ)+531_{c∈V(v}_{ₙ}₎( [symbol] +½×sign( [symbol] )). (21)

The alphabet of APPs for Sign-Preserving decoders is given by [symbol] ₐₚₚ={−(N_{q}×(dᵥ+1)+(dᵥ+ξ)/2), . . . , −1,0,+1, . . . ,+(N_{q}×(dᵥ+1)+(dᵥ+ξ)/2)}. From the APP, \hat{x}ₙ can be computed as \hat{x}ₙ =sign(Iₙ) if [symbol] =0, otherwise, \hat{x}ₙ=sign( [symbol] ) for n=1, . . . ,N.

### Sign-Preserving Noise-Aided Min-Sum Decoders

In order to define the noisy version of the SP-MS decoder, named Sign-Preserving Noise-Aided Min-Sum (SP-NA-MS) decoder, we first introduce the constraints on the noise models, and then we present a noise model that we use to perturb noiseless decoders.

### 1. Probabilistic Error Model for SP-NA-MS Decoders

We assume that the noisy message alphabet is denoted by [symbol] ₛ. The noisy message [symbol] is obtained after corrupting the noiseless message [symbol] with noise. To simplify the notations is this section, we use mᵤ to denote any [symbol] and \tilde{m} to denote any

[symbol]

DE analysis of SP-NA-MS decoders can be performed only using memoryless noise models which must satisfy the following condition of symmetry

Pr(\tilde{m}=ψ₂|mᵤ=ψ₁)=Pr(\tilde{m}=−ψ₂|mᵤ=−ψ₁), ∀ψ₁∈ [symbol] ᵤ and ψ₂∈ [symbol] ₛ.

This noise model injects some randomness at the VNU of SP-NA-MS decoders. Thus the noisy-VNU is symmetric, allowing to use the all-zero codeword assumption necessary in DE. Since the addition of noise in VNUs is independent of the sign of the messages, we will suppose in the sequel without loss of generality that the messages mᵤ and \tilde{m} are always positive.

Now, let us denote γ: [symbol] ᵤ→ [symbol] ₛ the function which transforms mᵤ∈ [symbol] ᵤ into \tilde{m}=γ(mᵤ)∈ [symbol] ₛ with the random process defined by the conditional probability density function (CPDF) Pr(\tilde{m}|mᵤ). In this document, the CPDF Pr(\tilde{m}|mᵤ) for the noise model γ is given by

$$Pr ( \tilde{m} \vert {m}_{u} ) = \{ \begin{matrix}1 , & if \tilde{m} = {m}_{u} = + 0 or if \tilde{m} = + {N}_{q} , {m}_{u} > + {N}_{q} , \\ φ ( {m}_{u} ) , & if \tilde{m} = {m}_{u} - 1 , ∀ {m}_{u} ∈ \{ + 1 , + 2 , … , + {N}_{q} \} , \\ 1 - φ ( {m}_{u} ) , & if \tilde{m} = {m}_{u} , ∀ {m}_{u} ∈ \{ + 1 , + 2 , … , + {N}_{q} \} , \\ 0 , & otherwise .\end{matrix} \qquad ( 22 )$$

where φ(mᵤ) is defined as

$$φ ( {m}_{u} ) = \{ \begin{matrix}{φ}_{0} , & if & {m}_{u} = + {N}_{q} , \\ {φ}_{a} , & if & {m}_{u} ∈ \{ + 2 , … , + ( Nq - 1 ) \} , \\ {φ}_{s} , & if & {m}_{u} = + 1 ,\end{matrix} \qquad ( 23 )$$

The noise model analyzed is parametrized by three different transition probabilities φ=(φₛ,φₐ,φ₀). The choice of these three transition probabilities is a compromise between complexity and the process of the border effects in [symbol] ₛ.

The reasoning behind γ is to implement a probabilistic offset with the purpose of always keeping the sign of the messages. With φ=(φₐ,φₐ,φₐ), we can implement the SP-MS decoder setting φₐ=0 and the SP-OMS with λᵥ=1 setting φₐ=1. The effect of the noise on the extreme values of the message alphabet [symbol] ₛ is studied with φₛ and φ₀. Thanks to γ, we can implement a SP-NA-MS decoder whose behaviour is a probabilistic weighted combination of a SP-MS decoder and a SP-OMS decoder. As an example, γ is depicted in FIG. 3 for (q=3, N_{q}=3).

### 2. Sign-Preserving Noise-Aided Min-Sum Decoders

A SP-NA-MS decoder is defined by injecting some randomness during the VNU processing. The SP-NA-MS decoder is implemented perturbing unsaturated v-to-c messages [symbol] with noise. Hence, the update rule for a noisy-VNU is given by

[symbol]

=γ( [symbol] ), (24)

We can note that γ is a symmetric function that performs the saturation function.

### Density Evolution for Sign-Preserving Decoders

The goal of DE is to recursively compute the probability mass function (PMF) of the exchanged messages in the Tanner graph along the iterations. DE allows us to predict if an ensemble of LDPC codes, parametrized by its degree distribution, decoded with a given MP decoder, converges to zero error probability in the limit of infinite block length.

In order to derive the DE equations for Sing-Preserving decoders, [symbol] , k ∈ [symbol] ₛ, denote the PMF of noiseless c-to-v messages in the [symbol] ^{th} iteration. Similarly, let [symbol] (k), k ∈ [symbol] ₛ, denote the PMF of noiseless v-to-c messages in the [symbol] ^{th} iteration. Also, let Ω⁽⁰⁾(k), k ∈ A_{L}, be the initial PMF of messages sent at [symbol] =0. To deduce the noisy DE equations, let [symbol] (k), k ∈ [symbol] ₛ, denote the PMF of noisy v-to-c messages in the [symbol] ^{th} iteration. We consider that the all-zero codeword is sent over the BI-AWGN channel.

### Initialization

DE is initialized with the PMF of the BI-AWGN channel with noise variance σ² as follows

$$\begin{matrix}{p}_{vtoc}^{( 0 )} ( k ) = \{ \begin{matrix}F ( k ) & if & k = - {N}_{q} \\ F ( k ) - F ( k - 1 ) & if & - {N}_{q} < k \leq - 1 \\ F ( 0 ) - F ( - 1 ) & if & k = - 0 \\ F ( 1 ) - F ( 0 ) & if & k = + 0 \\ F ( k + 1 ) - F ( k ) & if & + 1 \leq k < + {N}_{q} \\ 1 - F ( k ) & if & k = + {N}_{q}\end{matrix} & ( 25 ) \\ where F ( k ) = \frac{1}{\sqrt{2 π} {σ}_{n}} {\int }_{- ∞}^{k} {e}^{- {( t - {μ}_{n} )}^{2} / 2 {σ}_{n}^{2}} fsimi & \\ dt , & ( 26 ) \\ with {σ}_{n} = ( 2 / σ ) \times α and {μ}_{n} = ( 2 / {σ}^{2} ) \times α . & \end{matrix}$$

DE update for CNU

The input of a CNU is the PMF of the noisy messages going out of a noisy VNU, i.e. [symbol] . For a CN of degree d_{c}, [symbol] is given by

[symbol]

=Σ(₁, . . . , i_{d}_{_{c}}₋₁):Ψ_{c}(i₁, . . . ,i_{d}_{_{c}}₋₁)=k [symbol] (i₁) . . . [symbol] (i_{d}_{_{c}}₋₁), 0.1 cm∀k ∈ [symbol] ₛ. (27)

Considering the diffe-rent connection degrees of CNs of irregular LDPC codes, we have

[symbol]

=Σ_{d}_{_{c}}₌₂^{d}^{_{c,max}}ρd_{c}× [symbol] (k), 0.3 cm ∀k ∈ [symbol] ₛ (28)

DE update for VNU

We know that γ perturbs unsaturated values. For this reason, we first compute the PMF of unsaturated v-to-c messages of a VN of degree dᵥ, i.e. [symbol] , with the following equation

[symbol]

(k)Σ(t,i₁, . . . ,i_{d}_{ᵥ}₋₁):Ψᵥ(t,i₁, . . . ,i_{d}_{ᵥ}_{31 1})=kΩ⁽⁰⁾(t) [symbol] (i₁) . . . [symbol] (i_{d}_{ᵥ}₋₁), 0.1 cm ∀k ∈ [symbol] _{U}. (29)

And second, the noise effect is added to the PMF of unsaturated v-to-c messages to obtain the corrupted PMF

[symbol]

(k)= [symbol] (i)×p_{γ} (i,k), 0.1 cm ∀k ∈ [symbol] ₛ, (30)

where p_{γ} is the transition probability of the VN noise, p_{γ} also performs the saturation effect.

In this document, we use only the transition probabilities of the noise model γ defined here above. Although of course other noise models can be used.

Then the effect of the different connection degrees of VNs is considered using the following relation

[symbol]

(k)=∈_{d}_{ᵥ}₌₂^{d}^{_{v,max}}λ_{d}_{ᵥ}× [symbol] (k), 0.3 cm ∀k ∈ [symbol] ₛ (31)

For SP-NA-MS decoders, the DE update for VNU is implemented with (29), (30), and (31) where the effect of noise injection is added at VNUs. We can deduce that the DE update for VNU of SP-MS decoders setting p_{γ}(i,k)=1 if i=k, otherwise p_{γ}(i,k)=0, i.e. φ32 (0,0,0).

### Asymptotic Bit Error Probability

The asymptotic bit error probability can be deduced from the PMF of the APPs, which is obtained from the DE equations. Let [symbol] denote the bit error probability at iteration [symbol] , which is computed from the PMF of all incoming messages to a VN in the [symbol] ^{th} iteration, and defined by (f) I ^{.}0

[symbol]

=½ [symbol] (0)+Σ_{i=-(N}_{_{q}}_{×(d}_{_{v,max}}_{+1)+(d}_{_{v,max}}_{+ξ)/2)}⁻¹ [symbol] ⁽i) (32)

where [symbol] (k), k ∈ [symbol] ₐₚₚ, denotes the PMF of the APP at the end of the [symbol] ^{th} iteration for Sign-Preserving decoders. We can compute [symbol] (k) as follows

[symbol]

λ_{d}_{ᵥ}× [symbol] (k), 0.3 cm ∀k ∈ [symbol] ₐₚₚ

where [symbol] (k) is computed as

$$= {\sum }_{( t , {i}_{1} , … , {i}_{{d}_{v}} ) : {Ψ}_{v} ( t , {i}_{1} , … , {i}_{{d}_{v}} ) = k} {Ω}^{( 0 )} ( t ) ( {i}_{1} ) … ( {i}_{{d}_{v}} ) , ∀ k ∈ {app}_{}$$

The evolution of [symbol] with the iterations characterizes whether the Sign Preserving decoder converges or diverges in the asymptotic limit of the codeword length. When the number of iterations [symbol] goes to infinity, we obtain the asymptotic error probability pₑ^{(+∞)}. For SP-MS decoders which is a noiseless decoder, the decoder converges to zero error probability and successful decoding is declared, i.e. pₑ^{(+∞)}=0.

In the case of SP-NA-MS decoders, contrary to the noiseless case, pₑ^{(+∞)} is not necessarily equal to zero when the noisy DE converges and corrects the channel noise. It depends mainly on the chosen error model and the computing units to which it is applied. For noisy decoders, the lower bound of the asymptotic bit error probability, denoted pₑ^{(lb)}, has a mathematical expression that we can compute, but for other noise models is very difficult to find it. Hence, the bit error probability is lower-bounded as [symbol] ≥pₑ^{(lb)}>0.

### Density Evolution threshold

The DE threshold δ is expressed as a crossover probability (δ=ε*) for the BSC or as a standard deviation (δ=σ*) for the BI-AWGN channel, with the objective of separating two regions of channel noise parameters. The first region composed of values smaller than δ corresponds to the region where the DE converges to the zero error probability fixed point in less than Lₘₐₓ iterations of the DE recursion. The second region composed of values greater than δ corresponds to when the DE does not converge. In this later case, the DE converges to a fixed point which does not represent the zero error probability. Then the DE threshold can be considered as a point of discontinuity between these two regions.

We compute the DE threshold performing a dichotomic search and stopping when the bisection search interval size is lower than some precision prec. The DE estimation procedure is performed choosing a target residual error probability η>pₑ^{(lb)}, and declaring convergence of the noisy DE recursion when pₑ^{(+∞)} is less than or equal to η.

The noisy-DE threshold is a function of the code family, parametrized by its degree distribution (λ(x),ρ(x)), of the number of precision bits q, of the value of the channel gain factor α, and of the values of the transition probabilities of the noise model (φₛ,φₐ,φ₀). The algorithm 1 describes the procedure to compute the noisy-DE threshold a for the SP-NA-MS decoders for a fixed precision q, a fixed degree distribution (λ(x),ρ(x)), a fixed channel gain factor a, and a fixed noise model parameters (φₛ,φₐ,φ₀).

For the BI-AWGN channel, δ is the maximum value of σ or the minimum SNR at which the DE converges to a zero error probability can be expressed as

$${δ}_{db} = 10 {log}_{10} ( \frac{1}{2 R {σ}^{* 2}} )$$

where σ*=δ, and R is the rate of the code.

In this paper, we use δ to jointly optimize the noise model parameters (φₛ,φₐ,φ₀) and the channel gain factor a for a fixed precision q and a fixed degree distribution (λ(x),ρ(x)) as follows

$$( {φ}_{s}^{*} , {φ}_{a}^{*} , {φ}_{0}^{*} , {α}^{*} ) = arg {max}_{( {φ}_{s} , {φ}_{a} , {φ}_{0} , α )} \{ \tilde{δ} ( λ ( x ) , ρ ( x ) , q , α , ( {φ}_{s} , {φ}_{a} , {φ}_{0} ) ) \} . \qquad ( 33 )$$

The optimization of the transition probabilities of the noise model γ, and the channel gain factor a is made using a greedy algorithm which computes a local maximum DE threshold. For noiseless decoders, the optimization (33) is reduced to the optimum channel gain factor a* which is computed performing a grid-search.

### Asymptotic Analysis of Sign-Preserving Min-Sum Decoders

### Asymptotic Analysis of SP-MS Decoders for Regular LDPC Codes

In this section, we consider the ensemble of (dᵥ,d_{c})-regular LDPC codes with code rate R ∈ {1/2,3/4} for dᵥ ∈ {3,4,5}, R=0.8413 for the IEEE 802.3 ETHERNET code, and quantized decoders with q ∈ {3,4}.

The DE thresholds of the noiseless classical MS and OMS decoders are given in Table 2. It can be seen that the OMS is almost always superior to the MS for the considered cases, except for the regular dᵥ=3 LDPC codes with low precision q=3.

TABLE 2
DE thresholds of classical MS and OMS decoders
(dᵥ, d_{c},)-regular LDPC code, BI-AWGN channel

| | | (dᵥ, = 3, d_{c}, =6) | | (dᵥ = 4, d_{c} = 8) | | (dᵥ = 5, d_{c} = 10) | | (dᵥ = 6, d_{c} = 32) | |
|---|---|---|---|---|---|---|---|---|---|
| q | λᵥ | α* | δ_{db} | α* | δ_{db} | α* | δ_{db} | α* | δ_{db} |
| 3 bits | 0 | 0.9375 | 1.7888 | 0.8125 | 2.7360 | 0.6300 | 3.4117 | 0.455 | 4.0812 |
| | 1 | 1.0625 | 2.2039 | 1.25 | 2.3219 | 1.1500 | 2.7079 | 0.84 | 3.5928 |
| 4 bits | 0 | 2.0 | 1.6437 | 1.625 | 2.5389 | 1.2500 | 3.1772 | 1.035 | 3.8154 |
| | 1 | 1.875 | 1.3481 | 1.75 | 1.7509 | 1.5900 | 2.2306 | 1.28 | 3.1685 |
| 5 bits | 0 | 4.0 | 1.6132 | 3.25 | 2.4948 | 2.3000 | 3.1126 | 1.985 | 3.7506 |
| | 1 | 2.625 | 1.2154 | 2.0 | 1.7061 | 1.6900 | 2.2089 | 1.45 | 3.1400 |

| | | (dᵥ = 3, d_{c} = 12) | | (dᵥ = 4, d_{c} = 16) | | (dᵥ = 5, d_{c} = 20) | |
|---|---|---|---|---|---|---|---|
| q | λᵥ | α* | δ_{db} | α* | δ_{db} | α* | δ_{db} |
| 3 bits | 0 | 0.625 | 2.7316 | 0.6875 | 3.1550 | 0.5600 | 3.6449 |
| | 1 | 0.9375 | 3.1343 | 0.9375 | 3.0632 | 0.9200 | 3.2312 |
| 4 bits | 0 | 1.25 | 2.5646 | 1.375 | 2.9441 | 1.4000 | 3.3917 |
| | 1 | 1.5 | 2.4484 | 1.5 | 2.5292 | 1.3900 | 2.7620 |
| 5 bits | 0 | 2.5 | 2.5268 | 2.75 | 2.8991 | 2.4700 | 3.3373 |
| | 1 | 2.25 | 2.3040 | 1.875 | 2.4606 | 1.6100 | 2.7238 |

In Table 3, we indicate the noisy and noiseless DE thresholds obtained with (33), we also show the DE gains obtained comparing the best thresholds indicated in bold in Table 2 and the noisy (resp. noiseless) thresholds of SP-NA-MS decoders (resp. SP-MS decoders). Moreover, we list the best noisy DE thresholds of NAN-MS decoders.

TABLE 3
Noisy DE thresholds of SP-NA-MS decoders and DE
thresholds of SP-MS decoders

| | | SP-NA-MS decoders | | | | | | NAN-MS | SP-MS decoders | | | |
|---|---|---|---|---|---|---|---|---|---|---|---|---|
| (dᵥ, d_{c}) | q | α* | φₛ* | φₐ* | φₒ* | \tilde{δ}_{db} | DE gain | \tilde{δ}_{db} - NIV | α* | (φₛ*, φₐ*, φₒ*) | \tilde{δ}_{db} | DE gain |
| (3, 6) | 3 bits | 0.96 | 0.987 | 0.712 | 0.000 | 1.4994 | 0.2894 | 1.5711 | 0.95 | (1, 1, 0) | 1.5096 | 0.2792 |
| | 4 bits | 1.79 | 1.000 | 1.000 | 0.000 | 1.2688 | 0.0793 | 1.2877 | 1.79 | (1, 1, 0) | 1.2688 | 0.0793 |
| (3, 12) | 3 bits | 0.72 | 1.000 | 0.725 | 0.000 | 2.5421 | 0.1895 | 2.5989 | 0.71 | (1, 1, 0) | 2.5468 | 0.1848 |
| | 4 bits | 1.34 | 1.000 | 0.938 | 0.000 | 2.3596 | 0.0888 | 2.3777 | 1.36 | (1, 1, 0) | 2.3600 | 0.0884 |
| (4, 8) | 3 bits | 1.01 | 0.900 | 1.000 | 1.000 | 1.9820 | 0.3399 | 2.1056 | 1.01 | (1, 1, 1) | 1.9824 | 0.3395 |
| | 4 bits | 1.54 | 1.000 | 1.000 | 1.000 | 1.7306 | 0.0203 | 1.7411 | 1.54 | (1, 1, 1) | 1.7306 | 0.0203 |
| (4, 16) | 3 bits | 0.75 | 1.000 | 0.962 | 0.712 | 2.7448 | 0.3184 | 2.8121 | 0.78 | (1, 1, 1) | 2.7459 | 0.3173 |
| | 4 bits | 1.30 | 1.000 | 1.000 | 1.000 | 2.4941 | 0.0351 | 2.5077 | 1.30 | (1, 1, 1) | 2.4941 | 0.0351 |
| (5, 10) | 3 bits | 1.12 | 1.000 | 1.000 | 0.987 | 2.4908 | 0.2171 | 2.6417 | 1.12 | (1, 1, 1) | 2.4908 | 0.2171 |
| | 4 bits | 1.57 | 1.000 | 1.000 | 1.000 | 2.2196 | 0.0110 | 2.2306 | 1.57 | (1, 1, 1) | 2.2196 | 0.0110 |
| (5, 20) | 3 bits | 0.87 | 1.000 | 1.000 | 0.838 | 3.0106 | 0.2206 | 3.1400 | 0.89 | (1, 1, 1) | 3.0137 | 0.2175 |
| | 4 bits | 1.39 | 1.000 | 1.000 | 1.000 | 2.7412 | 0.0208 | 2.7596 | 1.39 | (1, 1, 1) | 2.7412 | 0.0208 |
| (6, 32) | 3 bits | 0.74 | 1.000 | 1.000 | 1.000 | 3.3963 | 0.1965 | 3.5766 | 0.74 | (1, 1, 1) | 3.3963 | 0.1965 |
| | 4 bits | 1.18 | 1.000 | 1.000 | 1.000 | 3.1787 | −0.0102 | 3.1685 | 1.18 | (1, 1, 1) | 3.1787 | −0.0102 |

Several conclusions can be derived from this analysis. First, the DE thresholds of the SP-NA-MS decoders are almost always better than the DE thresholds of the noiseless classical decoders. The DE gains for the SP-NA-MS decoders are quite important for q=3, the largest gain obtained is around 0.3399 dB for (dᵥ=4,d_{c}=8). While the DE gains are smaller for the largest precision q=4. We can observe a loss of around 0.0102 dB for (dᵥ=6,d_{c}=32) and q=4. From this analysis, we can conclude that the preservation of the sign of messages and the noise injection are more and more beneficial as the decoders are implemented in low precision. Second, when comparing the noisy thresholds of SP-NA-MS and NAN-MS decoders, one can observe that the SP-NA-MS decoders achieve better DE thresholds for almost all (dᵥ,d_{c})-regular LDPC codes tested, the only exception appears for the regular (dᵥ=6,d_{c}=32) LDPC code and q=4. The largest gain obtained, when comparing the SP-NA-MS thresholds and NAN-MS thresholds, is around 0.1803 dB for the regular (dᵥ=6,d_{c}=32) LDPC code and q=3. A third remark comes from the interpretation of the optimum φ* obtained through the DE analysis. We have φ*₀=0 for regular dᵥ=3 LDPC codes, this makes sense because dᵥ=3 is small enough to transform \hat{m}=±1 into \tilde{m}=±0, which gives to [symbol] a reliability of zero and which could not help to extrinsic messages become more and more reliable at each new decoding iteration. For regular dᵥ>3 LDPC codes, we have almost always 6100 *₀=1, hence, one can conclude that for regular dᵥ>3 LDPC codes, the transformation from \hat{m}=±1 to \tilde{m}=±0, does not affect the decoding process. Note that in [?], the transformation from \hat{m}=±1 to \tilde{m}=0 should not be allowed since \tilde{m}=0 ∈ A_{c} erase the bit value. Finally, all SP-NA-MS decoders can be implemented as deterministic decoders since the values of the transition probabilities are close or equal to 0 or 1. The optimum noise parameters φ* are close to (φ*ₛ,φ*ₐ,φ*₀)=(1,1,0) for the regular dᵥ=3 LDPC codes. While in the case of the regular dᵥ>3 LDPC codes, φ* are close to (φ*ₛ,φ*ₐ,φ*₀)=(1,1,1) which correspond to a deterministic SP-OMS decoder.

### Asymptotic Analysis of SP-MS Decoders for Irregular LDPC codes

In the previous section we have seen that the optimum noise parameters (φ*ₛ,φ*ₐ,φ*₀) and the respective gains of SP-NA-MS decoders depend on the VN degree. For LDPC codes with irregular VN distribution, we propose therefore to extend our approach by considering a noise injection model γ with different values of the transition probabilities for the different connection degrees.

We denote by γ⁽²⁾:φ⁽²⁾=(φₛ⁽²⁾,φₐ⁽²⁾,φ₀⁽²⁾) the model which injects noise at VNs of degree dᵥ=2. Similarly, let γ⁽³⁾:φ⁽³⁾=(φₛ⁽³⁾,φₐ⁽³⁾,φ₀⁽³⁾) denote the noise model for the VNs of degree dᵥ=3. Finally, we decide to use the same model for all other VNs with degrees dᵥ≥4, denoted γ^{(≥4)}:φ^{(≥4)}=(φₛ^{(≥4)},φₐ^{(≥4)},φ₀^{(≥4)}).

The optimization of the transition probabilities for an irregular LDPC code with distribution (λ(x),ρ(x)) is still performed by the maximization of the noisy DE thresholds:

$$( {φ}^{( 2 ) *} , {φ}^{( 3 ) *} , {φ}^{( \geq 4 ) *} , {α}^{*} ) = arg {max}_{( {φ}^{( 2 )} , {φ}^{( 3 )} , {φ}^{( \geq 4 )} , α )} \{ \tilde{δ} ( λ ( x ) , ρ ( x ) , q , α , {φ}^{( 2 )} , {φ}^{( 3 )} , {φ}^{( \geq 4 )} ) \} . \qquad ( 34 )$$

For our analysis, we consider the ensemble of irregular LDPC codes which follow the distribution of the rate R ∈ {1/2,3/4}, length N=2304 code described in the WIMAX ₇2_{6 x +}2₇4_{6 x2 +}3₇0_{6 xs} standard. The degree distribution for the rate 1/2 code is λ(x)=22/76x+24/76x²+30/76x⁵ and ρ(x)=48/76x⁵+28/76x⁶, while for the rate 3/4 B code is λ(x)=10/88x+36/88x²+42/88x⁵ and ρ(x)=28/88x¹³+60/88x¹⁴. For these distributions, we indicate in Table 4 the DE thresholds of the noiseless MS decoder and the noiseless OMS decoder.

TABLE 4
DE thresholds of noiseless MS decoders and noiseless OMS decoders with
offset value λ_{ν} = 1 for the WIMAX degree distribution
Irregular LDPC code, BI-AWGN channel

| | |
|---|---|
| R = 1/2 | R = 3/4 |

| q | λ_{ν} | α* | δ_{db} | α* | δ_{db} 1* |
|---|---|---|---|---|---|
| 3 bits | 0 | 0.44 | 1.8310 | 0.66 | 2.8236 |
| | 1 | 0.40 | 5.2283 | 0.50 | 3.4406 |
| 4 bits | 0 | 1.07 | 1.3941 | 1.29 | 2.6150 |
| | 1 | 0.80 | 2.8140 | 1.42 | 2.2416 |
| 5 bits | 0 | 2.30 | 1.3013 | 2.50 | 2.5654 |
| | 1 | 1.55 | 1.1828 | 1.97 | 2.1637 |

Noisy DE thresholds are summarized in Table 5, where we indicate the optimum values of a and of the noise parameters for the different degrees. Those results confirm the conclusions of the regular LDPC codes analysis: (i) the DE thresholds of SP-NA-MS decoders are better than the DE thresholds of NAN-MS decoders, (ii) the optimum value for φ*₀ is 0 or it is close to 0 for dᵥ=3 VNs and for q=3, and (iii) some of the optimized models are not probabilistic since the optimized values of the transition probabilities are very close to 0 or 1.

TABLE 5
DE thresholds of SP-NA-MS and SP-MS decoders
for the WIMAX degree distribution

| | | SP-NA-MS decoders | | | | | | | NAN-MS | SP-MS decoders | | | |
|---|---|---|---|---|---|---|---|---|---|---|---|---|---|
| R | q | α* | dᵥ | φₛ* | φₐ* | φₒ* | \tilde{δ}_{db} | DE gain | \tilde{δ}_{db}-NIV | α* | (φₛ*, φₐ*, φₒ*) | \tilde{δ}_{db} | DE gain |
| ½ | 3 bits | 0.65 | 2 | 0.000 | 0.000 | 0.000 | 1.3997 | 0.4313 | 1.6236 | 0.65 | (0,0,0) | 1.4003 | 0.4307 |
| | | | 3 | 0.000 | 0.162 | 0.000 | | | | | (0,0,0) | | |
| | | | ≥ 4 | 1.000 | 1.000 | 1.000 | | | | | (1,1,1) | | |
| | 4 bits | 1.24 | 2 | 0.000 | 0.000 | 0.000 | 0.9547 | 0.4394 | 0.9995 | 1.24 | (0,0,0) | 0.9582 | 0.4359 |
| | | | 3 | 0.250 | 1.000 | 0.375 | | | | | (0,1,0) | | |
| | | | ≥ 4 | 1.000 | 1.000 | 1.000 | | | | | (1,1,1) | | |
| ¾ | 3 bits | 0.81 | 2 | 0.000 | 0.000 | 0.000 | 2.4433 | 0.3803 | 2.5323 | 0.81 | (0,0,0) | 2.4451 | 0.3785 |
| | | | 3 | 1.000 | 0.687 | 0.000 | | | | | (1,1,0) | | |
| | | | ≥ 4 | 1.000 | 1.000 | 1.000 | | | | | (1,1,1) | | |
| | 4 bits | 1.48 | 2 | 1.000 | 0.788 | 0.000 | 2.2110 | 0.0306 | 2.2138 | 1.49 | (1,1,0) | 2.2111 | 0.0305 |
| | | | 3 | 1.000 | 1.000 | 1.000 | | | | | (1,1,1) | | |
| | | | ≥ 4 | 1.000 | 1.000 | 1.000 | | | | | (1,1,1) | | |

Another conclusion can be driven from these tables. From the DE analysis we can conclude that the noise should not be injected on degree dᵥ=2 VNs for the case of low precision q=3, since we obtain always (φₛ⁽²⁾,φₐ⁽²⁾,φ₀⁽²⁾)≃(0,0,0). While for the largest precision q=4, the noise should be injected on degree dᵥ=2 VNs for some cases. These observations, combined with the fact that the optimum values for φ^{(≥4)}* are always 1, lead to the conclusion that injecting noise in SP-NA-MS decoders for irregular LDPC codes is especially important for the degree dᵥ=3 VNs (inject the noise on degree dᵥ=2 VNs will be depend on the degree distribution and the precision used)

Finally, the gains for SP-NA-MS decoder for irregular codes are larger than for the regular codes. The gain of the rate 1/2 code is 0.4313 dB for the lower precision q=3, and 0.4394 dB for the largest precision q=4. In the case of the rate 3/4 B code, the gains for the two considered precision q=3 and q=4 are smaller than the rate 1/2 code, a gain of 0.3803 dB for q=3, and a gain of 0.0306 dB for q=4.

### Finite Length Performance

In this section we present the frame error rate (FER) performance for noiseless classical MS, noiseless classical OMS, and SP-MS decoders. We analyze the quantized decoder performance over the BI-AWGN channel.

The considered decoders are the ones with the best DE thresholds, indicated in bold in Table 2 and Table 3. The noiseless classical OMS decoder performance for quantization q=5 are also show as benchmark.

A maximum of 100 iterations has been set for dᵥ=3, dᵥ=4, and dᵥ=5 LDPC decoders. FIG. 4 shows the FER performance comparisons between the classical MS, classical OMS, and SP-MS decoders, for the two considered precisions q=3 and q=4, and for the regular (dᵥ=3, d_{c}=6) QC-LDPC code. FIG. 5 and FIG. 6 draw the same curves for the regular (dᵥ=4, d_{c}=8) QC-LDPC code and the regular (dᵥ=5, d_{c}=10) QC-LDPC code, respectively.

A first conclusion is that the finite length FER performance are in accordance with the gains predicted by the DE analysis. We observe in the waterfall (i.e. at FER=10⁻²) an SNR gain for the SP-MS decoders which corresponds to the threshold differences (Table 3 and Table 5): around 0.27 dB (q=3,dᵥ=3,R=1/2), 0.06 dB for (q=4,dᵥ=3,R=1/2), 0.32 dB for (q=3,dᵥ=4,R=1/2), the same performance for (q=4,dᵥ=4,R=1/2), 0.20 dB for (q=3,dᵥ=5,R=1/2), the same performance for (q=4,dᵥ=5,R=1/2). We have made the same analysis for LDPC codes with rate R=3/4, i.e. (dᵥ=3,d_{c}=12), (dᵥ=4,d_{c}=16), and (dᵥ=5,d_{c}=20), and obtained the same conclusions.

Simulation results for the IEEE 802.3 ETHERNET code are provided on FIG. 7 with a maximum of 30 iterations. Again, the SNR gains in the waterfall correspond to what was predicted with the DE analysis, with a 0.19 dB gain for q=3 and the same performance for q=4.

Similarly, FIG. 8 and FIG. 9 present simulation results for the WIMAX rate 1/2 LDPC code and the WIMAX rate 3/4 B LDPC code, respectively, for a maximum of 100 iterations. We observe again that the SNR gains in the waterfall region are in agreement with the gains predicted by the DE analysis, with a 0.40 dB gain for (q=3, R=1/2), a 0.40 dB gain for (q=4, R=1/2), a 0.37 dB gain for (q=3, R=3/4), and a 0.03 dB gain for (q=3, R=3/4).

Additionally, for the WIMAX rate 1/2 LDPC code, the 3-bit SP-MS decoder has the same FER performance as the 4-bit MS decoder. In the waterfall region, the 4-bit SP-MS decoder has the same FER performance as the 5-bit OMS decoder, while in the error floor region, the 5-bit OMS decoder has better FER performance than the 4-bit SP-MS decoder. In the case of the WIMAX rate 3/4 B LDPC code, The SP-MS decoders have better FER performance than the MS and the OMS decoders in the error floor region.

As a remark, we can also see that the preservation of the sign of messages does not seem to have an influence in the error floor of the decoders, since all the curves have similar slopes in the low FER region. This means that the preservation of the sign of messages does not correct the dominant error events due to trapping sets.

The study presented in details here above is a particular case where q_{ch}=q A_{L}=A_{S}=A_{C}.

Another particular case of study occurs when q_{ch}=q+1, and A_{L}≠A_{S}=A_{C}. For these conditions some results obtained in the study of the IEEE 802.3 ETHERNET code are presented.

In the initialization stage of the SP-MS decoder, i.e. first iteration, the variable-to-check messages are computed as mᵥ_{ₙ}_{→c}_{ₘ}⁽¹⁾=min(max(Iₙ,−N_{q}), +N_{q}) where cₘ ∈ V₍ᵥₙ₎.

First, we present the DE thresholds δ obtained for different precision q_{ch} and q. The following table shows the DE thresholds for optimized SP-MS decoders.

| (dᵥ, d_{c}) | (q_{ch}, q) | α | δ |
|---|---|---|---|
| (6, 32) | (3, 2) | 0.74 | 3.3979 |
| | (3, 3) | 0.74 | 3.3963 |
| | (4, 3) | 1.22 | 3.1740 |
| | (4, 4) | 1.18 | 3.1787 |

From the table we can conclude that the SP-MS decoder implemented with precision q_{ch}=3 and q=2 (resp. q_{ch}=4 and q=3) has the same performance as the SP-MS decoder implemented with precision q_{ch}=q=3 (resp. q_{ch}=q=4). In the implementation part this has a great impact, since it goes from the precision q=q_{ch} of the messages to the precision q=q_{ch}−1, this reduces the number of wires between VNs and CNs in an ASIC implementation.

Simulation results for the IEEE 802.3 ETHERNET code are provided on FIG. 13 with a maximum of 30 iterations. From the finite length FER performance, we can conclude that the performances of the SP-MS are in accordance with the performances predicted by the DE analysis.

In general, the choice of the alphabets A_{L}, A_{S}, and A_{C} (i.e. the precision of LLRs, v-to-c messages, and c-to-v messages) will depend on the code with which the SP-MS decoder works. FIG. 14 illustrates the performances of the SP-MS decoder in comparison with other decoders. Considering the case of q_{ch}=q+1 and A_{L}≠A_{S}=A_{C} for the regular (dᵥ=4,d_{c}=8) QC-LDPC code, we can note in the FIG. 14 that the SP-MS decoder exhibits poor performance having an early error floor. Note that for q=2, we have A_{S}=A_{C}={−1 ,−0, +0,+1} and A_{L}={−3,−2,−1,−0,+0,+1,+2,+3}. In FIG. 14 one can also see that the SP-MS decoder considering q_{ch}=q and A_{L}=A_{S}=A_{C} has the best performance. We have A_{L}=A_{S}=A_{C} ={−3,−2,−1,−0,+0,+1 ,+2,+3} for q=3. Another particular case of study occurs when considering A_{L}=A_{S}≠A_{C}, this means that the precision of the v-to-c messages m_{vn→cm}^{(I)} and the c-to-v m(cₘ→vₙ^{(I)} messages are different. Let us consider the case of q_{ch}=3 bits of precision for the LLR and the v-to-c messages, hence A_{L}=A_{S}={−3,−2,−1,−0,+0,+1,+2,+3}. Let us also consider the case of q=2 bits of precision for the c-to-v messages, hence A_{C}={−1,−0,+0,+1}. The CNs have 3-bit inputs and must generate 2-bit outputs. Using the update rule at CN, see equation (14), the c-to-v m_{cm→vn}^{(I)} messages belongs to the alphabet A_{S}, i.e. q_{ch}=3 bits of precision. In order to use q=2 bits of precision for the c-to-v messages we consider the following mapping.

$$= \{ \begin{matrix}( sign ( ) , 0 ) , if abs ( ) & ∈ \{ 0 , 1 \} and if < 11 \\ ( sign ( ) , 1 ) , if abs ( ) & ∈ \{ 2 , 3 \} and if < 11 \\ ( sign ( ) , 0 ) , if abs ( ) & ∈ \{ 0 \} and if \geq 11 \\ ( sign ( ) , 1 ) , if abs ( ) & ∈ \{ 1 , 2 , 3 \} and if \geq 11\end{matrix} \qquad$$

Then the c-to-v messages belong to the alphabet A_{C}. In the VNs, the c-to-v messages with amplitude abs(m_{cm→vn}^{(I)})=1 are interpreted as messages of amplitude 2. With this interpretation the VNs perform the update rules. Simulations results using a maximum of 100 iterations are provided on FIG. 14. From the results we can see that the SP-MS decoder with A_{L}=A_{S}≠A_{C} has better performance than the MS and the OMS decoders. Comparing the SP-MS decoders, we clearly observe that the best SP-MS decoder is obtained using the same precision for messages and LLRs. We can also see that the early appearance of the error floor is eliminated by using 3 bits for the v-to-c messages and 2 bits for the c-to-v messages. In the implementation part this has a great impact because the number of wires in an ASIC implementation is reduced. It can be observed that for example A_{L}≠A_{S}=A_{C} can be a good choice for the IEEE 802.3 ETHERNET code, A_{L}=A_{S}=A_{C} can be a good choice for the WIMAX rate 1/2 LDPC code, and A_{L}=A_{S}≠A_{C} can be a good choice for the regular (dᵥ32 4,d_{c}=8) QC-LDPC code.

A person of skill in the art would readily recognize that steps of various above-described methods can be performed by programmed computers. Herein, some embodiments are also intended to cover program storage devices, e.g., digital data storage media, which are machine or computer readable and encode machine-executable or computer-executable programs of instructions, wherein said instructions perform some or all of the steps of said above-described methods. The program storage devices may be, e.g., digital memories, magnetic storage media such as a magnetic disks and magnetic tapes, hard drives, or optically readable digital data storage media. The embodiments are also intended to cover computers programmed to perform said steps of the above-described methods.

The functions of the various elements shown in the figures, including any functional blocks labeled as “processors”, may be provided through the use of dedicated hardware as well as hardware capable of executing software in association with appropriate software. When provided by a processor, the functions may be provided by a single dedicated processor, by a single shared processor, or by a plurality of individual processors, some of which may be shared. Moreover, explicit use of the term “processor” or “controller” should not be construed to refer exclusively to hardware capable of executing software, and may implicitly include, without limitation, digital signal processor (DSP) hardware, network processor, application specific integrated circuit (ASIC), field programmable gate array (FPGA), read only memory (ROM) for storing software, random access memory (RAM), and non volatile storage. Other hardware, conventional and/or custom, may also be included. Similarly, any routers shown in the figures are conceptual only. Their function may be carried out through the operation of program logic, through dedicated logic, through the interaction of program control and dedicated logic, or even manually, the particular technique being selectable by the implementer as more specifically understood from the context.

As used in this application, the term “circuitry” may refer to one or more or all of the following:
hardware-only circuit implementations (such as implementations in only analog and/or digital circuitry) and
combinations of hardware circuits and software, such as (as applicable):
a combination of analog and/or digital hardware circuit(s) with software/firmware and
any portions of hardware processor(s) with software (including digital signal processor(s)), software, and memory(ies) that work together to cause an apparatus, such as a mobile phone or server, to perform various functions) and
hardware circuit(s) and or processor(s), such as a microprocessor(s) or a portion of a microprocessor(s), that requires software (e.g., firmware) for operation, but the software may not be present when it is not needed for operation.

This definition of circuitry applies to all uses of this term in this application, including in any claims. As a further example, as used in this application, the term circuitry also covers an implementation of merely a hardware circuit or processor (or multiple processors) or portion of a hardware circuit or processor and its (or their) accompanying software and/or firmware. The term circuitry also covers, for example and if applicable to the particular claim element, a baseband integrated circuit or processor integrated circuit for a mobile device or a similar integrated circuit in server, a cellular network device, or other computing or network device.

It should be appreciated by those skilled in the art that any block diagrams herein represent conceptual views of illustrative circuitry embodying the principles of the invention. Similarly, it will be appreciated that any flow charts, flow diagrams, state transition diagrams, pseudo code, and the like represent various processes which may be substantially represented in computer readable medium and so executed by a computer or processor, whether or not such computer or processor is explicitly shown.

The description and drawings merely illustrate the principles of the invention. It will thus be appreciated that those skilled in the art will be able to devise various arrangements that, although not explicitly described or shown herein, embody the principles of the invention and are included within its spirit and scope. Furthermore, all examples recited herein are principally intended expressly to be only for pedagogical purposes to aid the reader in understanding the principles of the invention and the concepts contributed by the inventor(s) to furthering the art, and are to be construed as being without limitation to such specifically recited examples and conditions. Moreover, all statements herein reciting principles, aspects, and embodiments of the invention, as well as specific examples thereof, are intended to encompass equivalents thereof.

Algorithm 1 - Computation of the noisy DE threshold

```
1) [Initialization]
  Initialize interval limits [\tilde{δ}₁, \tilde{δ}₂] with \tilde{δ}₁ < \tilde{δ}₂, such that DE succeeds
  for \tilde{δ} = \tilde{δ}₁ and fails for \tilde{δ} = \tilde{δ}₂. Further define \tilde{δ}ₘ = (\tilde{δ}₁ + \tilde{δ}₂)/2
2) [While |\tilde{δ}₂ − \tilde{δ}₁| > prec]
  a) [Perform noisy DE]
    i) [Initialize noisy DE]
      Noisy DE is initialized with the equation (15) and σ = \tilde{δ}ₘ
    ii) [Iteration Loop]
      A) [Compute PMF]
        Apply recursively the sequence of five equations (27), (28), (29),
        (30), and (31) for Lₘₐₓ iterations.
      B) [Break Iteration]
        The iteration loop breaks when either the pₑ⁽ [symbol] ⁾ ≤ η or Lₘₐₓ is
        reached.
  b) [Noisy DE succeeds]
    If pₑ⁽ [symbol] ⁾ ≤ η, the noisy DE has converged and we update \tilde{δ}₁ =\tilde{δ}ₘ, \tilde{δ}₂ =
    \tilde{δ}₂ and am = (\tilde{δ}₁ + \tilde{δ}₂)/2.
  c) [Noisy DE fails]
    If pₑ^{(L}^{ₘₐₓ}⁾ > η, the noisy DE has not converged and we update \tilde{δ}₁ = \tilde{δ}₁,
    \tilde{δ}₂ = \tilde{δ}ₘ and \tilde{δ}ₘ = (\tilde{δ}₁ + \tilde{δ}₂)/2.
  d) [Tolerance]
    Compute the size of the interval |\tilde{δ}₂ − \tilde{δ}₁| and stops the procedure if
    it is smaller than the threshold tolerance ( e.g. 10⁻¹⁰).
3) [Threshold]
  \tilde{δ} = \tilde{δ}ₘ is the noisy-DE threshold.
```

1. Iterative decoder configured for decoding a code composed of at least two constraint nodes and having a codeword length N, said decoder comprising:
N variable nodes (VNs) vₙ, n=1 . . . N, each variable node vₙ being configured to receive a log-likelihood ratio LLR Iₙ of the channel decoded bit n of the codeword to be decoded, said LLR Iₙ being defined on a alphabet A_{L} of q_{ch} quantization bits, q_{ch} being an integer equal or greater than 2;
M constraint nodes (CNs) cₘ, m=1 . . . M, 2≤M>N;
the variable nodes and the constraint nodes being the nodes of a Tanner graph; variable nodes and constraint nodes being configured to exchange messages along edges of the Tanner graph;
each variable node vₙ being configured for estimating the value yₙ of the n^{th} bit of the codeword to be decoded and for sending messages mᵥ_{ₙ}_{→c}_{ₘ}, messages belonging to an alphabet Aₛ of q quantization bits, q ≤q_{ch}, to the connected constraint nodes cₘ, the set of connected constraint nodes being noted V₍ᵥₙ₎, defining the degree dᵥ of the variable node vₙ, as the size of the set V₍ᵥₙ₎, and V_{(vn)\{cm}} being the set V₍ᵥₙ₎ except the constraint node cₘ, and then,
each constraint nodes cₘ being configured for testing the received message contents with predetermined constraints and sending messages m_{c}_{ₘ}_{→v}_{ₙ}, messages belonging to an alphabet A_{c} to the connected variable nodes vₙ;
the message emissions being repeated until the decoding of the codeword is achieved successfully or a predetermined number of iteration is reached; and
the LLR Iₙ and the messages mᵥ_{ₙ}_{→c}_{ₘ} and m_{c}_{ₘ}_{→v}_{ₙ} are coded according to a sign-and-magnitude code in the alphabets A_{L}, Aₛ and A_{c} symmetric around zero, A_{L}={−N_{qch}, . . . ,−1,−0,+0,+1, . . . ,+N_{qch}}, Aₛ={−N_{q}, . . . ,−1,−0,+0,+1, . . . ,+N_{q}}, A_{c}={−N_{q′}, . . . ,−1,−0,+0,+1, . . . ,+N_{q′}}in which the sign indicates the estimated bit value and the magnitude represents its reliability; and
each variable node vₙ, for each iteration l, is configured to compute:
sign-preserving factors, sum of the ponderated sign of LLR Iₙ and the sum of the signs of all messages, except for the message coming from cₘ, received from the connected constraint nodes at iteration I: [symbol]
=ξ×sign(Iₙ)+Σ_{c∈V(v}_{ₙ}_{)\{c}_{ₘ}_{}} sign ( [symbol] ) where ξ is a positive or a null integer;
messages to connected constraint nodes cₘ for iteration I+1 computed in two steps [symbol]
=Iₙ+1/2× [symbol] +Σ_{c∈V(v}_{ₙ}_{)\{c}_{ₘ}_{}}( [symbol] ) and [symbol]
=(sign( [symbol] ), [symbol] (floor(abs( [symbol] )))) where S is a function from the set of value that can take floor(abs( [symbol] ))to the set Aₛ.

2. The iterative decoder of claim 1 wherein ξ equal to 0 if dᵥ=2, equal to 1 if dᵥ>2 and dᵥ is odd, and equal to 2 if dᵥ>2 and dᵥ is even.

3. The iterative decoder of claim 1, wherein the constraints applied by the constraint nodes are parity check, convolution code or any block code.

4. The iterative decoder of claim 3, wherein the codeword is coded by LDPC and the constraint nodes are check nodes.

5. The iterative decoder of claim 1, wherein the function S is defined as S(x)=min(max(x−λ(x), 0),+Nq), where λ(x) is an integer offset value depending on the value of x.

6. The iterative decoder of claim 5, wherein λ(x) is a random variable that can take it value in a predefined set of values according to a predefined law.

7. The iterative decoder of claim 1, wherein alphabets Aₛ and A_{c} are identical.

8. The iterative decoder of claim 1 wherein the means comprises
at least one processor; and
at least one memory including computer program code, the at least one memory and computer program code configured to, with the at least one processor, cause the performance of the decoder.

9. An iterative decoding method for decoding a code composed of at least two constraint nodes and having a codeword length N, by an iterative decoder according to claim 1, said method comprising:
reception and storage (21) of the LLR Iₙ by the variable node vn, n=1 . . . N;
emission (23) of messages mᵥ_{ₙ}_{→c}_{ₘ};
verification (25) of the constraints by the constraint nodes cₘ;
emission (27) of messages m_{c}_{ₘ}₋ᵥ_{ₙ} containing a possible candidate value for the variable n solving the constraints;
computation (29) by the variable nodes of [symbol]
−ξ×sign (Iₙ)+Σ_{c∈V(v}_{ₙ}_{)\{c}_{ₘ}_{}} sign ( [symbol] ) where ξ is a positive or a null integer, and of messages to connected constraint nodes cₘ for iteration l+1 computed in two steps [symbol]
=Iₙ+1/2× [symbol] +Σ_{c∈V(v}_{ₙ}_{)\{c}_{ₘ}_{}}( [symbol] ) and [symbol]
=(sign( [symbol] ), [symbol] (floor(abs( [symbol] )))) where S is a function from the set of value that can take floor (abs( [symbol] )) to the set Aₛ; and
iteration from emission of messages mᵥ_{ₙ}_{→c}_{ₘ} to their computation for the next iteration until the codeword is decoded or the number of iteration reaches a predetermined count.

10. A computer readable medium encoding a machine-executable program of instructions to perform a method according to claim 9.
